(19) United States
(12) Patent Application Publication
(10) Pub. No.: US 2004/0188728 A1
(43) Pub. Date: Sep. 30, 2004

(54) CMOS image sensors

(75) Inventor: Lindsay Grant, Edinburgh (GB)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: STMicroelectronics Ltd., Globe Park (GB)

(21) Appl. No.: 10/781,977

(22) Filed: Feb. 19, 2004

(30) Foreign Application Priority Data
Feb. 21, 2003 (EP) 03251077.8

(51) Int. Cl. H01L 31/062; H01L 31/113; C30B 1/00; H01L 21/20; H01L 21/36

(52) U.S. Cl. 257/292

(57) ABSTRACT

A CMOS image sensor and method for making such a sensor includes a coating over the photosensing parts, wherein the coating performs a dual function. In fabrication, the coating prevents the formation of silicide, which is not optically opaque, on the photosensing parts. When the CMOS sensor is in use, the coating helps to couple light onto the photosensing parts, and therefore acts as an anti-reflective layer. The method of fabrication uses a self-aligning technique, which ensures pixel-to-pixel uniformity.

### FIELD OF THE INVENTION

The present invention relates to the field of semiconductor image sensors, and in particular, to CMOS image sensors.

### BACKGROUND OF THE INVENTION

CMOS image sensors typically comprise a matrix of pixels each containing a photosensing part, such as a photodiode, and other active or passive parts. CMOS image sensors are made with the same standard CMOS fabrication processes used in current high-volume wafer fabrication plants to produce IC devices, such as microprocessors, microcontrollers and DSPs. This means that signal processing and control circuits may be integrated on the same semiconductor material as the photosensing part and the other active or passive parts, thereby providing a low cost integrated imaging device. Also, CMOS image sensors can benefit from the advances made in the semiconductor industry.

Increasingly, in what is called a salicide-type process, silicide is applied to IC devices as part of a CMOS fabrication process. The formed silicide has the effect of reducing parasitic resistance and improving switching speed. However, refractory metal silicide suppresses transmission of light and is therefore unsuitable for application to devices including photosensing parts.

U.S. Pat. No. 6,160,282 discloses a CMOS image sensor pixel where the photosensing parts have been protected by silicon oxide from the formation of silicide. The sensor thereby gains from the improvements associated with silicide formation on some non-photosensing parts.

U.S. Pat. No. 5,903,021 discloses how the performance of a CMOS image sensor pixel may be improved by partially pinning the photo-diode. Pinning involves covering part of the surface of the photo-diode with a layer of semiconductor material of the same type as the substrate. As a consequence, the potential of the surface is pinned to the potential of the substrate. This increases the quantum efficiency of the photo-diode in addition to reducing its dark current and improving its blue color response, which is normally the weakest of all the color responses. As a result, the pixel performs to a high standard.

It has been shown by I. Murakami et al. in an article titled “Technologies to Improve Photo-Sensitivity and Reduce VOD Shutter Voltage for CCD Image Sensors” (IEEE Trans. Electron Devices, vol. 47, 2000, pp. 1566-1572), that quantum efficiency of a photodiode in an image sensor can be improved by applying an anti-reflective coating to increase light coupling.

Photo response uniformity is an important parameter for image sensors. This parameter can be limited by the uniformity of the photo-diode capacitance from pixel-to-pixel within the sensor matrix. Variation of the patterning of the implants within the pixel can also cause a reduction in the matching of photo response between pixels. One technique used to improve this matching is a self-aligning technique where a single master layer is used to define the implant areas. Each of the different implant areas may then be selected by use of a lower tolerance select mask while maintaining the good matching achieved by use of the single master layer.

### SUMMARY OF THE INVENTION

An object of the present invention is to provide a semiconductor image sensor comprising at least one pixel having a photosensing part, wherein the photosensing part has a coating which performs a dual function.

One of the dual functions may be a fabrication function. The fabrication function preferably prevents the formation of silicide. Another one of the dual functions may be an in-use function, such as an anti-reflection function.

The constituents and thickness of the coating may be optimized for maximum response at a particular wavelength. The photosensing part may comprise a photo-diode. The photodiode may be a pinned photodiode, or a partially pinned photodiode.

Another aspect of the present invention is directed to a method for making a semiconductor image sensor comprising forming at least one pixel having a photosensing part, and coating the photosensing part with a coating which performs a dual function.

### BRIEF DESCRIPTION OF THE DRAWINGS

The invention will now be described, by way of example, with reference to the drawings, in which:

FIG. 1 is a cross-sectional side view of a pixel in an image sensor according to the present invention.

FIG. 2(a) is a cross-sectional side view of a pixel in an image sensor with implant areas and silicon oxide islands formed and with a silicon dioxide layer and a silicon nitride layer according to the present invention.

FIG. 2(b) is a cross-sectional side view of a pixel in an image sensor as described in FIG. 2(a) with a layer of photoresist applied thereto.

FIG. 2(c) is a cross-sectional side view of a pixel in an image sensor as described in FIG. 2(b) after exposure to a suitable light source.

FIG. 2(d) is a cross-sectional side view of a pixel in an image sensor as described in FIG. 2(c) after removal of the unexposed photoresist.

FIG. 2(e) is a cross-sectional side view of a pixel in an image sensor as described in FIG. 2(d) after removal of the silicon nitride layer and silicon dioxide layer not below the exposed photoresist.

FIG. 3(a) is a cross-sectional side view of a pixel in an image sensor with a coating over the photosensitive area formed according to the present invention.

FIG. 3(b) is a cross-sectional side view of a pixel in an image sensor as described in FIG. 3(a) with a layer of titanium deposited thereon.

FIG. 3(c) is a cross-sectional side view of a pixel in an image sensor as described in FIG. 3(b) with a layer of silicide formed thereon except over the photosensitive area.

### DETAILED DESCRIPTION OF THE PREFERRED EMBODIMENTS

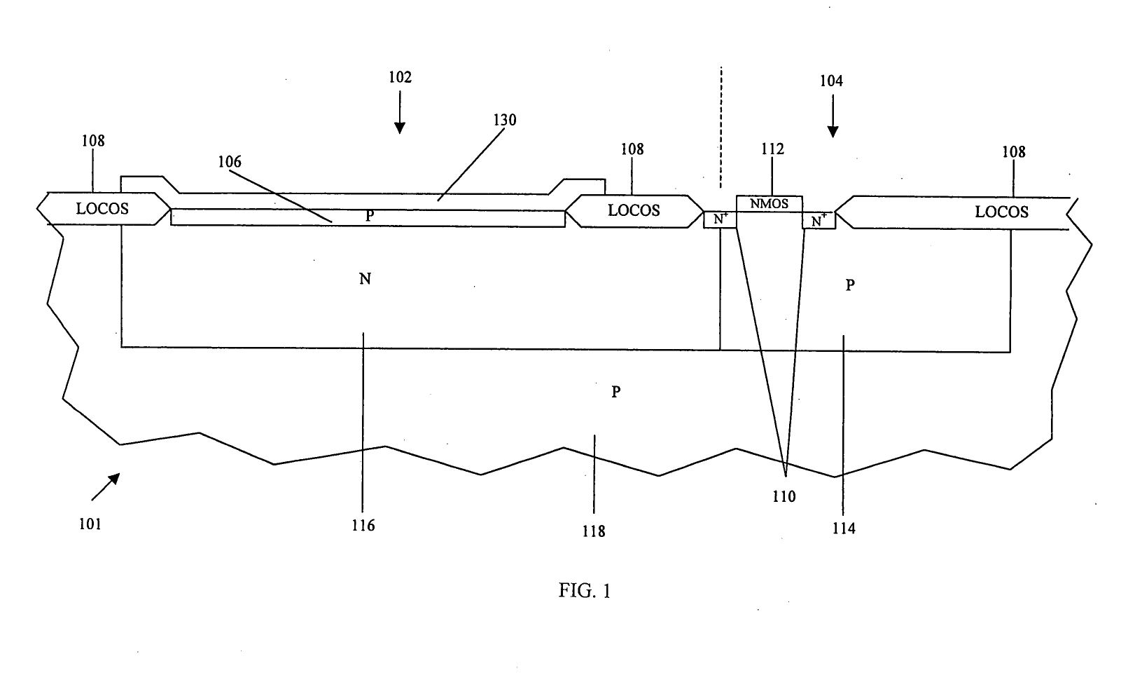

With reference to FIG. 1, a pixel indicated generally at 101 is formed on a p-type substrate 118 with a photosensing part 102 and an active part 104. The photosensing part 102 comprises a partially pinned photo-diode formed from an n-type well 116 within the substrate 118 and a p-type pinning layer 106 partially covering the n-type well 116. The active part 104 comprises an NMOS transistor formed from two spaced apart, highly doped n-type implants 110 in a p-type well 114. The n-type well 116 is positioned to connect the photo sensing and active parts 102, 104. The p-type pinning layer 106 has an anti-reflection coating 130 of silicon nitride on silicon dioxide.

The anti-reflection coating 130 increases light coupling to improve the photo-diode quantum efficiency. During fabrication of the pixel 101, which involves the use of a salicide-type process, the anti-reflection coating 130 also prevents the formation of salicide over the photo-diode. Thus, the coating 130 has a dual function.

With reference to FIG. 1, a pixel 101 is fabricated, prior to the creation of the implant regions 106 and 110 and application of the coating 130, using a well known self-alignment technique. This technique involves creating lands or regions 108 of silicon oxide between parts of the pixel 101. The regions 108 are formed on the surface of the pixel 101 by a process involving photolithography, while using a single master mask layer. The end result of this process is that the surface of the pixel 101 is blocked by silicon nitride everywhere apart from the areas where the regions 108 are to be formed. The pixel 101 is then heated in an oxygen atmosphere so that silicon oxide is formed in the unblocked regions. The silicon nitride blocking is subsequently removed, leaving the silicon oxide regions 108.

Creation of the regions 108 at this stage in the process allows the use of the edges of the regions 108 as reference axes. When each pixel 101 is created the width of the central region 108, in particular, is kept constant, through use of the same master mask layer. This ensures accurate spacing between the N⁺ region 110 of the active part 104, which is connected to the photosensitive part 102, and the pinning layer 106. Ensuring the accurate spacing between these parts is critical for pixel-to-pixel uniformity.

Two separate masks (not shown) are used for the creation of the implant parts 106, 110. Each of these masks covers the entire pixel surface except the specific implant part 106, 110. The width of the central region 108 allows for some error in placement of the appropriate mask on the pixel without compromising the uniformity between pixels.

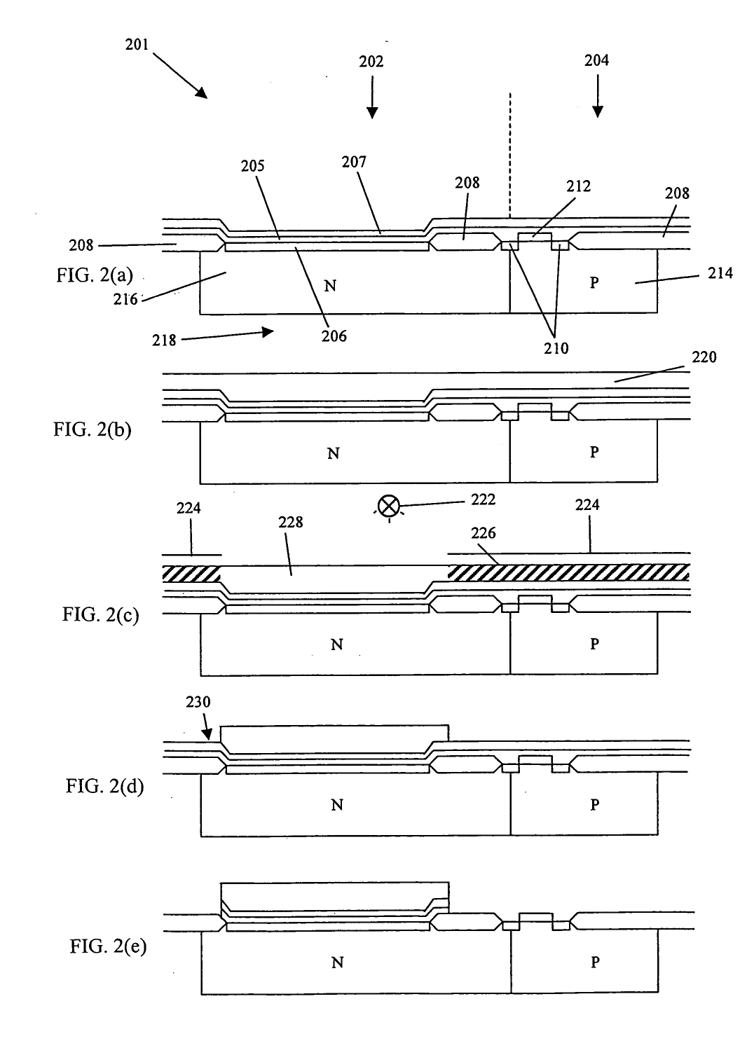

The coating 130, as shown in FIG. 1, is formed in a process as shown in FIG. 2. FIG. 2a shows a pixel 201 after the first step of the process, wherein a thin silicon dioxide layer 205 is formed over the exposed silicon. This silicon dioxide layer 205 may be formed by a number of different standard methods, including thermal oxidation or chemical vapor deposition. On top of the silicon dioxide layer 205, a silicon nitride layer 207 is formed. Formation of the silicon nitride layer 207 is made by use of a chemical vapor deposition (CVD) process. This may be either thermal or plasma enhanced CVD. The silicon dioxide layer 205 and the silicon nitride layer 207 together form a coating 230.

The thickness of the coating 230, over the photosensitive part 202, is controlled by the length of time of the CVD deposition to give an optimum thickness of 300 Å (±50 Å) of the silicon nitride layer 207 and 250 Å (±50 Å) of the silicon dioxide layer 205. However, because the coating has a dual function, the thickness of the coating 230 chosen is a balance between being thick enough to prevent silicide formation and being the correct optical path length to ensure an anti-reflective surface in the desired wavelength range. The peak transmission through the coating 230 is normally set to be a maximum at a wavelength of 450 nm. This acts to increase the quantum efficiency of the sensor to blue light, thereby improving color camera performance.

A layer of photoresist 220 is then applied to the whole surface of the pixel 201 (FIG. 2b). A mask 224 is then placed over the pixel 201 such that the photosensitive part 202 is not covered (FIG. 2c). The pixel 201 is then illuminated through the mask 224 to expose the uncovered photoresist 228. The light source 222 and the mask 224 are then removed as well as the unexposed photoresist 226. An etching step is used to remove the coating 230 from the surface of the pixel 201, everywhere apart from over the photosensitive part 202, which is protected from the etching step by the exposed photoresist 228. The photoresist 228 is then removed using a standard photoresist strip process, leaving a pixel 101 as shown in FIG. 1.

The salicide type process involves forming silicide on the surface of the pixel. The silicide has the effect of reducing parasitic resistances, and is therefore desirable. However, silicide hampers light transmission and is unsuitable for application to a photosensing part.

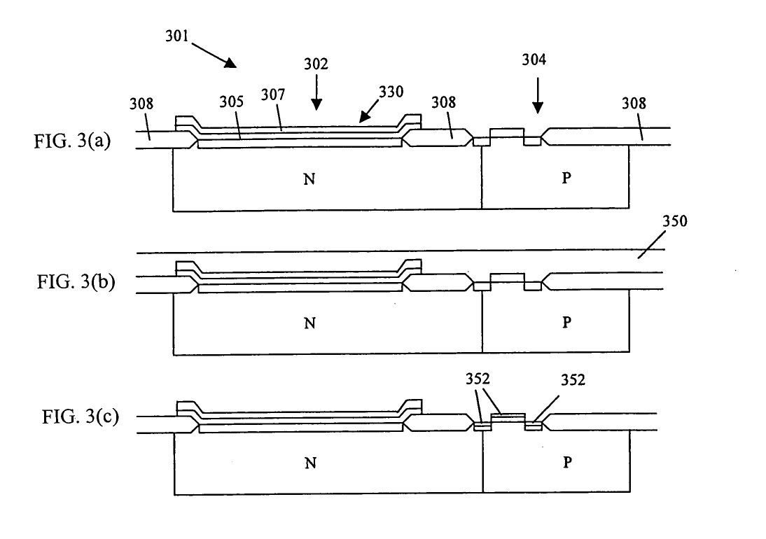

With reference to FIG. 3a, a pixel 301 is shown which has gone through the process required to provide the coating 330. A titanium layer 350 is deposited over the entire surface of the pixel 301 as shown in FIG. 3b. In a thermal treatment the titanium reacts with exposed silicon to form silicide 352 but does not react with the silicon nitride layer 307 or silicon dioxide layer 308. Unreacted titanium deposited on the silicon nitride coating and silicon dioxide may be removed in a wet processing step, as shown in FIG. 3c, leaving the coating as an anti-reflective layer.

1-16 (Cancelled).

17. A semiconductor image sensor comprising:
at least one pixel comprising a photosensing portion and a coating thereon that performs a dual function.

18. A semiconductor image sensor according to claim 17, wherein one of the dual functions of the coating comprises a fabrication function.

19. A semiconductor image sensor according to claim 18, wherein the fabrication function comprises the coating preventing silicide formation on the photosensing portion.

20. A semiconductor image sensor according to claim 17, wherein one of the dual functions of the coating comprises an in-use function.

21. A semiconductor image sensor according to claim 20, wherein the in-use function comprises the coating functioning as an anti-reflective surface.

22. A semiconductor image sensor according to claim 17, wherein the photosensing part comprises a photo-diode.

23. A semiconductor image sensor according to claim 22, wherein the photo-diode comprises a pinned photo-diode.

24. A semiconductor image sensor according to claim 22, wherein the photo-diode comprises a partially pinned photo-diode.

25. A semiconductor image sensor comprising:
a substrate; and
at least one pixel on said substrate and comprising a photosensing portion and a coating, the coating functioning as an anti-reflective surface and prevents formation of silicide on said photosensing portion.

26. A semiconductor image sensor according to claim 25, wherein the photosensing part comprises a photo-diode.

27. A semiconductor image sensor according to claim 26, wherein the photo-diode comprises a pinned photo-diode.

28. A semiconductor image sensor according to claim 26, wherein the photo-diode comprises a partially pinned photo-diode.

29. A method for making a semiconductor image sensor comprising:
forming at least one pixel comprising a photosensing portion; and
forming a coating on the photosensing portion that performs a dual function.

30. A method according to claim 29, wherein one of the dual functions of the coating comprises a fabrication function.

31. A method according to claim 30, wherein the fabrication function comprises the coating preventing silicide formation on the photosensing portion.

32. A method according to claim 29, wherein one of the dual functions of the coating comprises an in-use function.

33. A method according to claim 32, wherein the in-use function comprises the coating functioning as an anti-reflective surface.

34. A method according to claim 29, wherein forming the coating comprises a self-aligning technique.

35. A method according to claim 30, wherein the photosensing portion comprises a photo-diode.

36. A method according to claim 35, wherein the photo-diode comprises a pinned photo-diode.

37. A method according to claim 35, wherein the photo-diode comprises a partially pinned photo-diode.
